(19) United States
(12) Patent Application Publication
(10) Pub. No.: US 2020/0012184 A1
(43) Pub. Date: Jan. 9, 2020

(54) MASK FOR CURING OF SEALANT

(71) Applicant: WUHAN CHINA STAR OPTOELECTRONICS TECHNOLOGY CO., LTD, Wuhan, Hubei (CN)

(72) Inventor: Kaixiang ZHAO, Wuhan, Hubei (CN)

(73) Assignee: WUHAN CHINA STAR OPTOELECTRONICS TECHNOLOGY CO., LTD., Wuhan, Hubei (CN)

(21) Appl. No.: 15/539,745

(22) PCT Filed: May 16, 2017
(86) PCT No.: PCT/CN2017/084535

§ 371 Date: Jun. 26, 2017

(30) Foreign Application Priority Data
Apr. 21, 2017 (CN) 201710266443.9

(51) Int. Cl. G03F 1/26; G02F 1/13; G02F 1/1339

(52) U.S. Cl. CPC G03F 1/26; G02F 1/133514; G02F 1/1339; G02F 1/1303

(57) ABSTRACT

Disclosed is a mask for curing of a sealant, and the mask comprises a support plate. The support plate has a flat structure, which includes a first plane and a second plane. The first plane is provided with a shielding layer thereon. When the mask is used, it is placed in parallel with a liquid crystal panel coated with the sealant to be cured, and light for curing the sealant transmits through the mask and irradiates the liquid display panel. The support plate is transparent, and the shielding layer allows part of light to transmit through. Under a condition that a frame of a display panel becomes narrower, the mask for curing of the sealant according to the present disclosure can have a good performance, and thus incomplete curing of the sealant and decomposition of liquid crystal can be avoided.

### CROSS-REFERENCE TO RELATED APPLICATIONS

This application claims the priority of Chinese patent application CN201710266443.9, entitled “Mask for curing of sealant” and filed on Apr. 21, 2017, the entirety of which is incorporated herein by reference.

### FIELD OF THE INVENTION

The present disclosure relates to the technical field of liquid crystal display manufacturing, and in particular, to a mask for curing of a sealant.

### BACKGROUND OF THE INVENTION

Liquid crystal display (LCD) is a widely used flat display device. With the increasing demand for display devices, the technological innovation in the field of liquid crystal display manufacturing is also very rapid. In the prior art, a structure of a common LCD panel is as shown in FIG. 1, and the panel comprises a first substrate 1 and a second substrate 2 which are arranged in parallel, a frame 3 which is arranged along edges of the first substrate 1 and the second substrate 2 and configured to bind the first substrate 1 and the second substrate 2, and a liquid crystal region 4 which is obtained by injecting liquid crystal between the first substrate 1 and the second substrate 2. An active area 5 is located near a center of the liquid crystal region 4, and a non-active area 6 is a portion other than the active area 5 in the liquid crystal region 4. The first substrate 1 is provided with thin film transistors (TFT). The second substrate 2 is a color filter (CF) substrate. The rotation direction of liquid crystal molecules in a liquid crystal cell is controlled by changing signals and voltages on the TFTs so as to achieve the purpose of displaying by controlling the emission of polarized light at each pixel point.

The frame 3 can prevent liquid crystal materials between the first substrate 1 and the second substrate 2 from flowing thereout. During the procedure of manufacturing the liquid crystal cell, the frame 3 is obtained by curing a sealant. Therefore, the curing of the sealant is a very important step in the procedure of manufacturing liquid crystal cell. In the prior art, ultra violet curing (UVC) is a commonly used method for curing of the sealant. As shown in FIG. 1, when ultra violet (UV) light is used to cure the sealant, a mask (UV mask) is placed above a glass substrate to shield the liquid crystal region 4 in the glass substrate and to prevent the decomposition or denaturation of the liquid crystal molecules caused by radiation of the UV light. In the mask (UV mask), a metal layer is deposited on a glass plate 7. A metal layer 8 and a glass plate 7 together form a mask 9. The mask 9 is configured to shield the radiation of an ultraviolet light source 10 to the liquid crystal region. The mask 9 mainly plays a role of protecting the active area 5 from the radiation of the UV light.

FIG. 2 schematically shows a positional relationship between the mask and a display panel when viewed along a direction perpendicular to the mask from one side of the mask. In order to illustrate the operating principle of the mask, only the metal layer 8 of the mask 9, the active area 5 and the frame 3 are shown in FIG. 2, and other portions are omitted and not shown herein, which is apparent to those skilled in the art. In FIG. 2, a dashed-line box portion represents the active area 5, which is a display portion of the liquid crystal panel. The outermost frame 3 is arranged around the active area. The active area 5 and the frame 3 are portions of the display panel and thus in a same plane. As can be seen from FIG. 1 and FIG. 2, a shielding layer 8 of the mask 9 is located on another plane parallel to the display panel, and an edge of the shielding layer 8 as shown in FIG. 2 is a projection of the shielding layer 8 on the plane of the display panel. As shown in FIG. 2, a distance between an inner edge of the frame 3 and an edge of the active area 5 is a; a distance between the edge of the active area 5 and the projection of the edge of the metal layer 8 on the plane of the display panel is b; and a distance between the projection of the edge of the metal layer 8 on the plane of the display panel and the inner edge of the frame 3 is c.

The following problems always should be considered in the actual operation: (1) a machine base for curing of the sealant may has a certain error of alignment accuracy; (2) the mask itself has a certain fabrication error; and (3) the ultra violet light has a certain scattering, which may leads to the decomposition of the liquid crystal. In consideration of the above problems, there are certain constrains for values of a, b, and c. Nowadays, with the development of LCD panel technology and the demand for LCD panel, the frame of LCD panel becomes increasingly narrow. As the frame becomes narrower, a in FIG. 2 becomes smaller, which inevitability leads to the result that b and/or c become(s) smaller. If b is too small, as an area of the metal layer 8 is relatively reduced, the liquid crystal of the active region may be decomposed by UV radiation. When c is too small, the metal layer 8 may have a certain shielding to the sealant, which results in incomplete curing of the sealant. Based on a structure of the mask in the prior art, the defects of the mask in the prior art will become more and more obvious facing the condition that the frame of display panel becomes increasingly narrow. Hence, the mask in the prior art cannot cope with the condition that the display panel becomes increasingly narrow.

### SUMMARY OF THE INVENTION

In the prior art, a mask cannot cope with the condition that a display panel becomes increasingly narrow. In order to solve the above technical problem, the present disclosure provides a mask for curing of a sealant.

The present disclosure provides the mask for curing of the sealant, and the mask comprises a support plate. The support plate has a flat structure, and the flat structure comprises a first plane and a second plane. The first plane is provided with a shielding layer thereon. The support plate is transparent, and the shielding layer allows part of light to transmit through. When the mask is used, it is placed in parallel with a liquid crystal panel coated with the sealant to be cured, and light for curing the sealant transmits through the mask and irradiates the liquid crystal panel.

According to the present disclosure, based on the difference between a light intensity required in curing of a material of the sealant and a light intensity required in decomposition of liquid crystal, the shielding layer of the mask is arranged to allow part of light to transmit through. Under the condition that the sealant can be cured normally, it can be ensured that the liquid crystal does not decompose due to the light radiation. Hence, when a frame of the display panel becomes narrower, the mask for curing of the sealant in the present disclosure can well cope with the condition, and the incomplete curing of the sealant and the decomposition of the liquid crystal can be avoided.

As a further improvement on the present disclosure, the shielding layer comprises a complete shielding region and a partial shielding region. The complete shielding region is located at a center of the shielding layer, and the partial shielding is arranged around the complete shielding region. The partial shielding layer allows part of light to transmit through. When the mask is used, the complete shielding region is arranged corresponding to an active area and configured to shield the light from irradiating the active area.

The shielding layer is divided into the complete shielding region and the partial shielding region. The complete shielding region is arranged corresponding to the active area, and influence of weak light on the liquid crystal can be avoided. Moreover, the protection function of the mask for curing of the sealant according to the present disclosure to the active area can be ensured.

As a further improvement on the present disclosure, the partial shielding region comprises a light transmission structure arranged on the shielding layer, and the light transmission structure allows light to transmit through. When the mask is used, the partial shielding region is arranged corresponding to a non-active area and the sealant to be cured of the liquid crystal panel.

As a further improvement on the present disclosure, the light transmission structure comprises pore-like structures arranged through the shielding layer.

As a further improvement on the present disclosure, each of the pore-like structures is a circle or a polygon.

As a further improvement on the present disclosure, the light transmission structure comprises annular light transmission pores arranged around the complete shielding region.

As a further improvement on the present disclosure, the partial shielding region is configured to shield part of light irradiating the sealant to be cured on the liquid crystal panel. When the mask is used, a portion of the sealant to be cured near a center of the liquid crystal panel is located below the partial shielding region. The portion of the sealant to be cured is located below the partial shielding region, so that the other portion of the sealant can be completely radiated by the light in positions without the shielding layer. Therefore, the curing effect is better, the curing time is shortened, and the curing cost is reduced.

As a further improvement on the present disclosure, a light transmittance of the partial shielding region is in a range from 30% to 70%. The light transmittance can be selected according to actual needs. Considering properties of the frame and the liquid crystal materials used at present, the light transmittance in a range from 30% to 70% is reasonable.

As a further improvement on the present disclosure, the shielding layer is a metal layer. Since the metal layer is used as the shielding layer, a light shielding property thereof is good and the technology is mature.

As a further improvement on the present disclosure, the support plate is made of glass. As a common transparent material, glass is easy to obtain, and the cost thereof is low.

In conclusion, according to the present disclosure, since the shielding layer is arranged to allow part of light to transmit through, under the condition that the sealant can be normally cured, it can be ensured that the liquid crystal does not decompose due to the light radiation. Hence, under the condition that the frame of the display panel becomes narrower, the mask for curing of the sealant according to the present disclosure can well cope with the condition, and incomplete curing of the sealant and the decomposition of liquid crystal can be avoided.

### BRIEF DESCRIPTION OF THE DRAWINGS

The present disclosure will be described in a more detailed way below based on embodiments and with reference to the accompanying drawings, in the drawings:

FIG. 1 schematically shows a sectional view of a panel during curing of a sealant in the prior art;

FIG. 2 schematically shows a positional relationship between a mask and a display panel when viewed along a direction perpendicular to the mask from one side of the mask in FIG. 1;

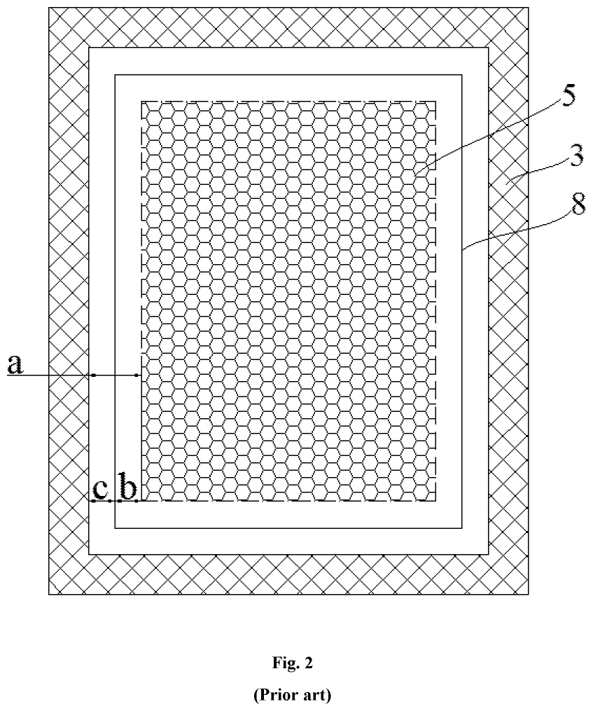

FIG. 3 schematically shows a sectional view of a panel during curing of a sealant according to a first embodiment of the present disclosure;

FIG. 4 is a front view of a mask for curing of the sealant according to the first embodiment of the present disclosure; and

FIG. 5 is a front view of a mask for curing of a sealant according to a second embodiment of the present disclosure.

In the drawings, the same components are represented by the same reference signs, and the size of each component does not represent the actual size of the corresponding component.

### DETAILED DESCRIPTION OF THE EMBODIMENTS

The present disclosure will be described in a more detailed way below with reference to the accompanying drawings. The terms “upper”, “lower”, “left”, and “right” in the following text are directions relative to the directions shown in the drawings, and should not be construed as limiting the scope of the disclosure.

In an existing liquid crystal panel material, a minimum illuminance of ultra violet light required to start a curing of the material of a sealant is relatively low, and the illuminance of the ultra violet light required for decomposition of a liquid crystal material is relatively high. Based on the above difference, a mask structure for curing of a sealant provided by the present disclosure can solve the problem in the prior art. A shielding layer is arranged to allow part of light to transmit through, so that a light intensity transmitting through a shielding payer 32 can be controlled. In this manner, the sealant can be cured by the light passing through the shielding layer 32, which does not damage liquid crystal at the same time.

### Embodiment 1

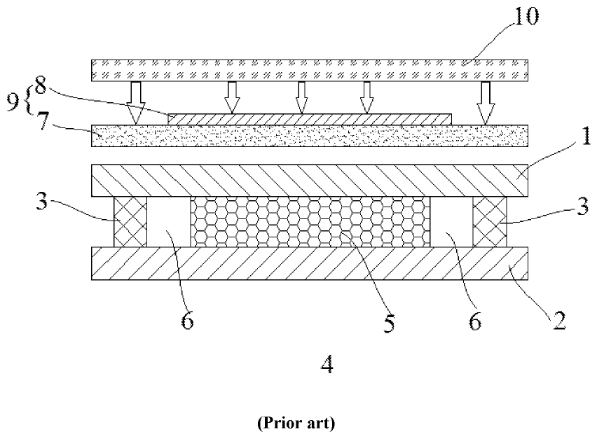

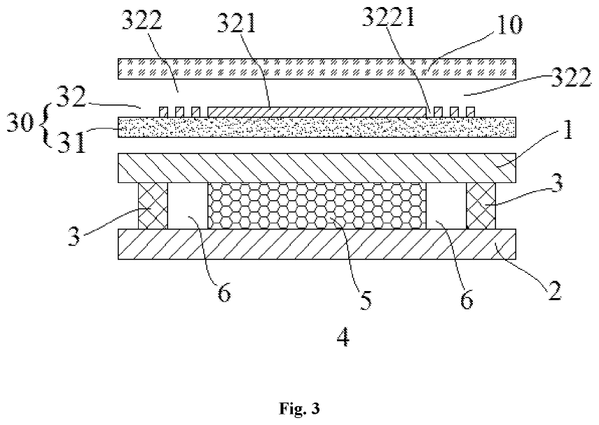

FIG. 3 schematically shows a sectional view of a panel during curing of a sealant according to the present embodiment. In order to illustrate a mask 30 for curing of a sealant according to the present disclosure conveniently, a structural relationship between a common liquid crystal panel structure in the prior art and the mask 30 for curing of the sealant is shown. The specific structure of the liquid crystal panel is the same as that of FIG. 1. Besides, similar to that in FIG. 1, FIG. 3 schematically shows an ultra violet light source 10 for curing of the sealant, which is not repeatedly described here. The mask 30 for curing of the sealant according to the present embodiment comprises a support plate 31, which has a transparent flat structure. The flat structure comprises a first plane 311 and a second plane 312. The first plane 311 is provided with a shielding layer 32 thereon, which allows part of light to transmit through. When the mask is used, it is placed in parallel with the liquid crystal panel coated with the sealant to be cured, and the light for curing the sealant transmits through the mask 30 and irradiates the liquid display panel.

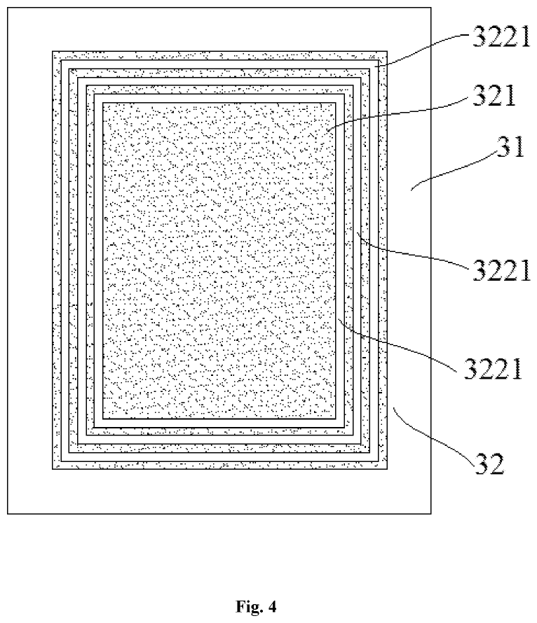

FIG. 4 is a front view of the mask for curing of the sealant according to the present embodiment. Combining FIG. 3 and FIG. 4, it can be seen that a partial light-transmission role of the shielding layer 32 according to the present embodiment is achieved by following structures. The shielding layer 32 comprises a complete shielding region 321 and a partial shielding region 322. The complete shielding region 321 is located at a center of the shielding layer 32, and the partial shielding region 322 is arranged around the complete shielding region 321. When the mask is used, the complete shielding region 321 is arranged corresponding to an active area 5 of a liquid crystal panel. The active area 5 is located below the complete shielding region 321, which is configured to shield light irradiating the active area 5, so that the light cannot transmit to the active area 5, and liquid crystal materials of the active area can be protected.

According to the present embodiment, the complete shielding region 321 has a rectangular structure, and the rectangular structure corresponds to a structure of the display panel. Based on the present embodiment, those skilled in the art can make arrangements to the complete shielding region 321 according to actual shape of the display panel. The partial shielding region 322 (a dashed line box portion in FIG. 3) comprises a plurality of pore-like structures running through the shielding layer 32, which are formed on the basis of the shielding layer. The pore-like structures allow the light to transmit through and are arranged around the rectangular structure. As shown in FIG. 3 and FIG. 4, the pore-like structures are annular light transmission pores 3221 arranged around the rectangular structure. Only three annular light transmission pores 3221 are shown in FIG. 3 and FIG. 4, which illustrates the present embodiment and does not represent an actual number of the annular light transmission pores 3221. In actual use, the number of the annular light transmission pores 3221 can be arranged according to specific sizes and light transmission requirements.

Preferably, since the partial shielding region 322 is configured to shield the sealant to be cured on the liquid crystal panel, a portion of the sealant to be cured near the center of the liquid crystal panel is located below the partial shielding region 322. That is, a portion of the sealant to be cured can be completely exposed by the curing light, and this arrangement is conducive to the curing of the sealant.

It should be noted that, FIG. 4 is the front view of the mask for curing of the sealant according to the present embodiment. In order to clearly show the annular light transmission pores 3221, a portion of the shielding layer 32 which does not belong to the annular light transmission pores 3221 is filled with a pattern. However, the filling is merely used to distinguish a translucent portion and an opaque portion of the shielding layer 32, and should not be regarded as a sectional view of the shielding layer 32.

### Embodiment 2

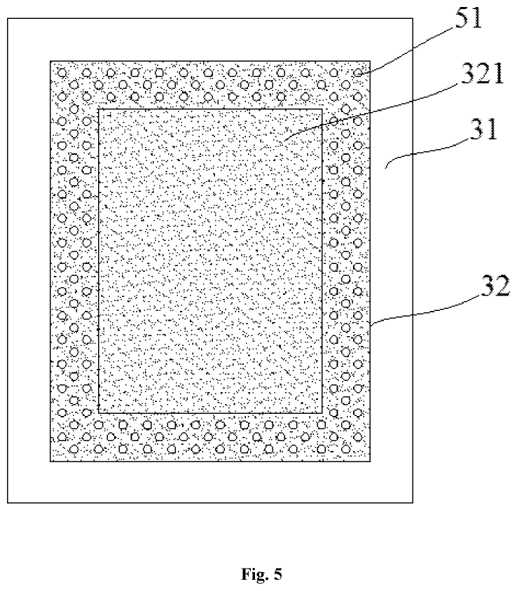

FIG. 5 is a front view of a mask for curing of a sealant according to the present embodiment. The present embodiment is different from the first embodiment in a structure of a partial shielding region 322. Other portions are the same as those in the first embodiment, and are not repeatedly described here.

According to the present embodiment, the effect that the partial shielding region 322 allows part of light to transmit through is achieved by a light transmission structure arranged on a shielding layer. As shown in FIG. 5, the light transmission structure comprises pore-like structures arranged through the shielding layer 32. According to the present embodiment, circular pore-like structures 51 are selected, and the circular pore-like structures are quite convenient to manufacture.

Preferably, the circular pore-like structures 51 are distributed uniformly in the partial shielding region 322.

Preferably, few circular pore-like structures 51 can be distributed near a complete shielding region 321, while more circular pore-like structures 51 can be distributed far from the complete shielding region 321. Specifically, few circular pore-like structures 51 can be arranged above a non-active area 6, while more circular pore-like structures 51 can be arranged above the sealant to be cured. This non-uniform design method allows the sealant to be irradiated by sufficient light, and the effect of the light on liquid crystal can be further reduced.

Certainly, the pore-like structures can also be provided with pores with other shapes, such as rectangular, oval, triangular, and other common shapes, which is not repeatedly described here.

In FIG. 5, a portion of the shielding layer 32 which does not belong to the circular pore-like structures is filled with a pattern. However, the filling is merely used to distinguish a translucent portion and an opaque portion of the shielding layer 32, and should not be regarded as a sectional view of the shielding layer 32.

Preferably, with respect to the partial shielding region, a light transmittance is a ratio of an area of the light transmission structure to an area of other portions of the partial shielding region. According to the present disclosure, the light transmittance of the partial shielding region is in a range from 30% to 70%. According to some embodiments, the light transmittance is preferably in a range from 50% to 60%. Those skilled in the art can suitably select the specific light transmittance according to different sealant materials and liquid crystal materials, which is not repeatedly described here.

Preferably, a material of the shielding layer 32 is generally selected from common metals, as long as the metal layer can isolate light from transmitting through. The light commonly used herein is ultra violet light.

Preferably, a support plate 31 can support the shielding layer 32. Hence, the support plate 31 should be transparent so as to allow the light to transmit through. The support plate 31 is commonly made of glass.

The present disclosure is explained in detail with reference to preferred embodiments hereinabove, but the embodiments disclosed herein can be improved or substituted with the equivalents without departing from the protection scope of the present disclosure. In particular, as long as there are no structural conflicts, the technical features disclosed in each and every embodiment of the present disclosure can be combined with one another in any way, and the combined features formed thereby are within the protection scope of the present disclosure. The present disclosure is not limited by the specific embodiments disclosed herein, but includes all technical solutions falling into the protection scope of the claims.

1. A mask for curing of a sealant, comprising a support plate, the support plate having a flat structure, the flat structure comprising a first plane and a second plane, the first plane being provided with a shielding layer thereon, the support plate being transparent, and the shielding layer allowing part of light to transmit through,
wherein when the mask is used, it is placed in parallel with a liquid crystal panel coated with the sealant to be cured, and the light for curing of the sealant transmits through the mask and irradiates the liquid display panel.

2. The mask for curing of the sealant according to claim 1, wherein the shielding layer comprises a complete shielding region and a partial shielding region, the complete shielding region being located at a center of the shielding layer, the partial shielding region being arranged around the complete shielding region, and the partial shielding region allowing part of light to transmit through; and
wherein when the mask is used, the complete shielding region is arranged corresponding to an active area of the liquid crystal panel and configured to shield the light from irradiating the active area.

3. The mask for curing of the sealant according to claim 2, wherein the partial shielding region comprises a light transmission structure arranged on the shielding layer, the light transmission structure allowing light to transmit through; and
wherein when the mask is used, the partial shielding region is arranged corresponding to a non-active area and the sealant to be cured of the liquid crystal panel.

4. The mask for curing of the sealant according to claim 3, wherein the light transmission structure comprises pore-like structures arranged through the shielding layer.

5. The mask for curing of the sealant according to claim 4, wherein each of the pore-like structures is a circle or a polygon.

6. The mask for curing of the sealant according to claim 3, wherein the light transmission structure comprises annular light transmission pores arranged around the complete shielding region.

7. The mask for curing of the sealant according to claim 2, wherein the partial shielding region is configured to shield part of light irradiating the sealant to be cured on the liquid crystal panel; and
wherein when the mask is used, a portion of the sealant to be cured near a center of the liquid crystal panel is located below the partial shielding region.

8. The mask for curing of the sealant according to claim 3, wherein the partial shielding region is configured to shield part of light irradiating the sealant to be cured on the liquid crystal panel; and
wherein when the mask is used, a portion of the sealant to be cured near a center of the liquid crystal panel is located below the partial shielding region.

9. The mask for curing of the sealant according to claim 4, wherein the partial shielding region is configured to shield part of light irradiating the sealant to be cured on the liquid crystal panel; and
wherein when the mask is used, a portion of the sealant to be cured near a center of the liquid crystal panel is located below the partial shielding region.

10. The mask for curing of the sealant according to claim 5, wherein the partial shielding region is configured to shield part of light irradiating the sealant to be cured on the liquid crystal panel; and
wherein when the mask is used, a portion of the sealant to be cured near a center of the liquid crystal panel is located below the partial shielding region.

11. The mask for curing of the sealant according to claim 6, wherein the partial shielding region is configured to shield part of light irradiating the sealant to be cured on the liquid crystal panel; and
wherein when the mask is used, a portion of the sealant to be cured near a center of the liquid crystal panel is located below the partial shielding region.

12. The mask for curing of the sealant according to claim 2, wherein a light transmittance of the partial shielding region is in a range from 30% to 70%.

13. The mask for curing of the sealant according to claim 3, wherein a light transmittance of the partial shielding region is in a range from 30% to 70%.

14. The mask for curing of the sealant according to claim 4, wherein a light transmittance of the partial shielding region is in a range from 30% to 70%.

15. The mask for curing of the sealant according to claim 5, wherein a light transmittance of the partial shielding region is in a range from 30% to 70%.

16. The mask for curing of the sealant according to claim 6, wherein a light transmittance of the partial shielding region is in a range from 30% to 70%.

17. The mask for curing of the sealant according to claim 7, wherein a light transmittance of the partial shielding region is in a range from 30% to 70%.

18. The mask for curing of the sealant according to claim 11, wherein a light transmittance of the partial shielding region is in a range from 30% to 70%.

19. The mask for curing of the sealant according to claim 1, wherein the shielding layer is a metal layer.

20. The mask for curing of the sealant according to claim 1, wherein the support plate is made of glass.
